(19) United States
(12) Patent Application Publication
(10) Pub. No.: US 2007/0238215 A1
(43) Pub. Date: Oct. 11, 2007

(54) Pressure transducer with increased sensitivity

(75) Inventors: Carl E. Stewart, Plano, TX (US); Peter G. Hancock, Plano, TX (US)

Correspondence Address: Bryan Anderson;Honeywell International Inc., 101 Columbia Rd., P.O. Box 2245, Morristown, NJ, 07962, US

(73) Assignee: Honeywell International Inc.

(21) Appl. No.: 11/399,854

(22) Filed: Apr. 7, 2006

(51) Int. Cl. H01L 21/00

(52) U.S. Cl. 438/53; 257/E31.001

(57) ABSTRACT

Silicon piezoresistor low pressure transducers can not be made cost effectively with a full scale output large enough to interface to control electronics. The size of the diaphragm, and therefore the size of the die required to produce a sufficient span make the die cost prohibitive. Simultaneously forming transistors and composite diaphragms with a common series of semiconductor processing steps supplies sensing elements and amplifier elements in close proximity. The transistors can be configured to amplify voltages or currents produced by piezoresistors located on the composite diaphragm to produce an output large enough to interface with control electronics. As such, a smaller die results in a cost effective transducer.

### TECHNICAL FIELD

Embodiments relate to sensors and piezoresistive sensing elements. Embodiments also relate to bipolar transistors. Embodiments additionally relate to semiconductor processing as applied to producing bipolar transistor, piezoresistors, and composite diaphragms.

### BACKGROUND OF THE INVENTION

Current technology supplies pressure transducers having composite diaphragms and piezoresistive elements. U.S. Pat. No. 6,528,340 and U.S. Pat. No. 6,796,193, both incorporated herein by reference, disclose pressure transducers that have composite diaphragms and piezoresistors. Systems and methods where the composite diaphragms and the piezoresistors are formed on a substrate through a series of semiconductor processing steps are also disclosed.

The current technology provides pressure transducers where pressure produces flex or strain on a composite diaphragm. The amount of flex or strain effects the resistance of piezoresistors. In one transducer, piezoresistors are attached to a composite diaphragm. In another transducer, piezoresistors are formed directly on the substrate. The piezoresistors can then be electrically configured to accept an input voltage and to produce an output voltage dependent on the amount of flex or strain on the composite diaphragm.

In some applications, the output voltage can be directly measured using an analog to digital converter or other device. The measurement can then be interpreted as a pressure reading. In other applications the output voltage must be amplified before it can be measured. Those skilled in the art of analog circuitry know of many different amplifier circuits that can be used to amplify the output voltage. For example, four piezoresistors attached to the composite diaphragm can be electrically configured as a wheatstone bridge to produce a high quality output voltage that is passed to a differential amplifier for amplification.

Passing a signal from a transducer to an amplifier adds noise to the signal. It is therefore advantageous to amplify an output voltage as close to a transducer as possible. The embodiments disclosed herein directly address the shortcomings of current systems and methods by locating amplifier circuit element very close to the composite diaphragm and to the piezoresistors.

### BRIEF SUMMARY

The following summary is provided to facilitate an understanding of some of the innovative features unique to the embodiments and is not intended to be a full description. A full appreciation of the various aspects of the embodiments can be gained by taking the entire specification, claims, drawings, and abstract as a whole.

It is therefore an aspect of the embodiments to obtain a substrate having a top and a bottom. The substrate can be a semiconductor wafer such as the p type substrates commonly used in semiconductor processing.

Another aspect of the embodiments is to create diffusion areas in the substrate top. For example, an implanter can be used to produce n type diffusion areas into a p type substrate. An epitaxial layer is then formed over the top. The diffusion areas spread into the epitaxial layer when it is formed. For example, n type diffusion areas spread into an n type epitaxial layer when it is formed over the previously discussed p type substrate.

A further aspect of the embodiments is to form junction isolations into the epitaxial layer to create transistor areas. Transistor areas lie over diffusion areas and within junction isolations. Creating a collector, base, and emitter within a transistor area results in the creation of a bipolar transistor. Those skilled in the art of semiconductor processing are familiar with the formation of junction isolations, collectors, bases, and emitters to produce bipolar transistors.

Yet another aspect of the embodiments is to form a composite diaphragm by etching the bottom. Etching processes such as those used in the incorporated references, U.S. Pat. No. 6,528,340 and U.S. Pat. No. 6,796,193, can etch patterns into the substrate with the epitaxial layer and the diffusion areas being etch stops. As such, some diffusion areas become transistor elements while others become composite diaphragm elements. The result is that transistors and composite diaphragms are simultaneously produced.

### BRIEF DESCRIPTION OF THE DRAWINGS

The accompanying figures, in which like reference numerals refer to identical or functionally similar elements throughout the separate views and which are incorporated in and form a part of the specification, further illustrate the present invention and, together with the background of the invention, brief summary of the invention, and detailed description of the invention, serve to explain the principles of the present invention.

FIG. 1 illustrates a pressure transducer in accordance with aspects of the embodiments;

FIG. 2 illustrates a plan view of diffusion areas in accordance with aspects of the embodiments;

FIG. 3 illustrates a stack with diffusion areas in accordance with aspects of the embodiments;

FIG. 4 illustrates a stack with diffusion areas and an epitaxial layer in accordance with aspects of the embodiments;

FIG. 5 illustrates a stack with diffusion areas, junction isolations, readouts, and an epitaxial layer in accordance with aspects of the embodiments;

FIG. 6 illustrates a stack with diffusion areas, junction isolations, readouts, piezoresistors, transistor elements, and an epitaxial layer in accordance with aspects of the embodiments;

FIG. 7 illustrates a plan view of junction isolations, readouts, piezoresistors, transistors, and an epitaxial layer in accordance with aspects of the embodiments;

FIG. 8 illustrates a composite diaphragm as seen from the bottom of a substrate in accordance with aspects of the embodiments;

FIG. 9 illustrates a high level flow diagram for simultaneously producing composite diaphragms and transistors in accordance with aspects of the embodiments; and

FIG. 10 illustrates a high level flow diagram for simultaneously producing composite diaphragms, piezoresistors, and transistors in accordance with aspects of the embodiments.

### DETAILED DESCRIPTION

The particular values and configurations discussed in these non-limiting examples can be varied and are cited merely to illustrate at least one embodiment and are not intended to limit the scope thereof. In general, the figures are not to scale.

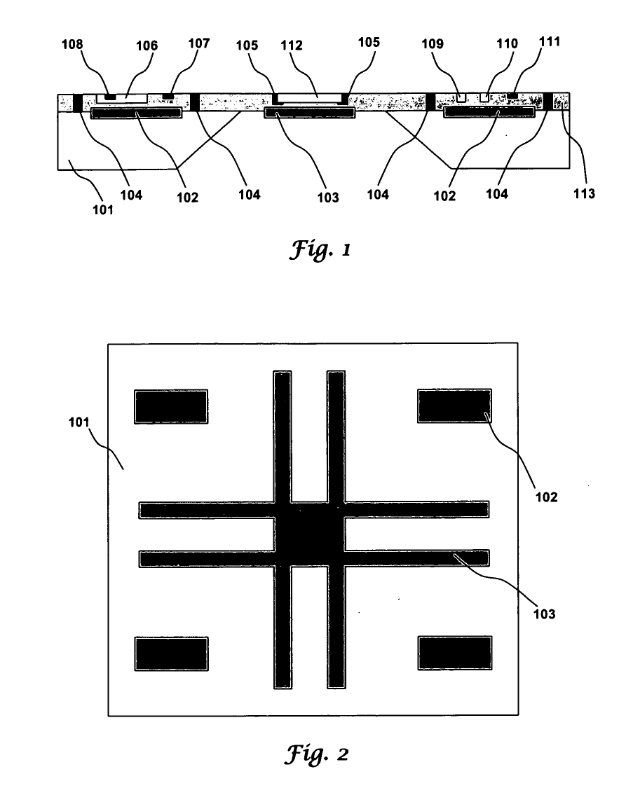

FIG. 1 illustrates a pressure transducer in accordance with aspects of the embodiments. A p type substrate 101 has n type diffusion areas 102, 103. An n-type epitaxial layer 113 covers the substrate 101. The diffusion areas 102, 103 have spread slightly into the epitaxial layer 113. Junction isolations 104 comprising p type material create transistor areas over some of the diffusion areas 102.

An npn transistor has a p type base 106, n type emitter 108, and n type collector 107. A pnp transistor has a p type emitter 109, p type collector 110, and an n type base 111.

Leadouts 105 of p type material lie on either side of a piezoresistor structure 112. The piezoresistor structure 112 can be a single piezoresistor, perhaps in a serpentine or similar pattern, or can be a group of piezoresistors in parallel or in series. The leadouts 105 supply convenient electrical connections on either side of the piezoresistor structure.

Wires can be bonded to the leadouts, bases, collectors, and emitters or can alternatively be formed using common semiconductor processing techniques. For example, aluminum wires can be created by a series of step including deposition, lithography, and etching. Those skilled in the art of semiconductor processing know of many techniques for creating wired connections between components on a die.

FIG. 2 illustrates a plan view of diffusion areas 102, 103 in accordance with aspects of the embodiments. The substrate 101 has been processed to produce diffusion areas 102, 103. Some diffusion areas 102 will become transistor elements. Other diffusion areas 103 will become composite diaphragm elements.

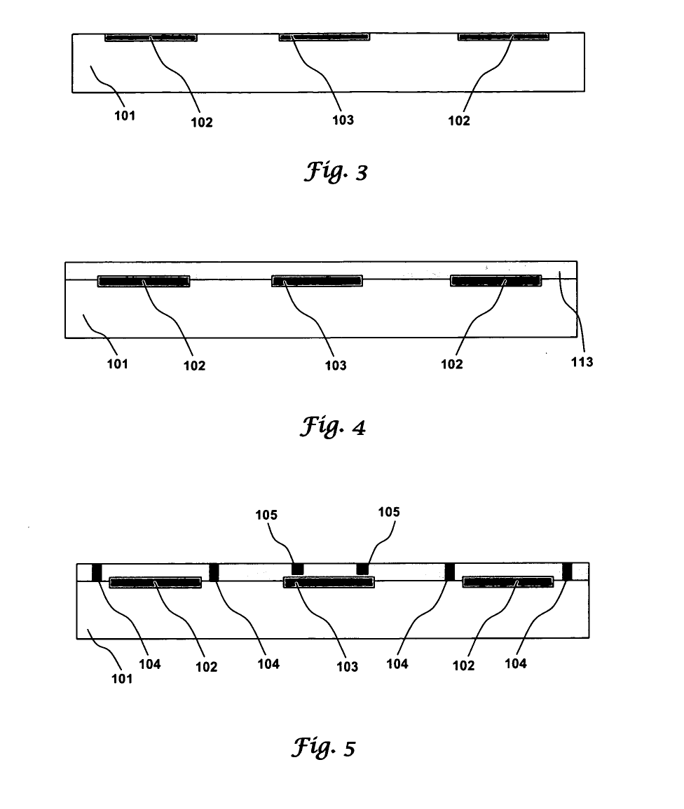

FIG. 3 illustrates a stack with diffusion areas 102, 103 in accordance with aspects of the embodiments. Those skilled in the art of semiconductor processing often use stacks to illustrate how materials are formed, layered and patterned onto a substrate. In FIG. 3, n type diffusion areas 102, 103 have been formed in the top of the p type substrate 101.

FIG. 4 illustrates a stack with diffusion areas 102, 103 and an epitaxial layer 113 in accordance with aspects of the embodiments. The FIG. 4 stack illustrates the result of creating an epitaxial layer 113 over the FIG. 3. stack. Notice that the diffusion areas 102, 103 have spread slightly into the epitaxial layer 113.

FIG. 5 illustrates a stack with diffusion areas 102, 103, junction isolations 104, readouts 105, and an epitaxial layer 113 in accordance with aspects of the embodiments. The FIG. 5 stack illustrates the formation of p type junction isolations 104 and p type readouts 105 into the FIG. 4 stack.

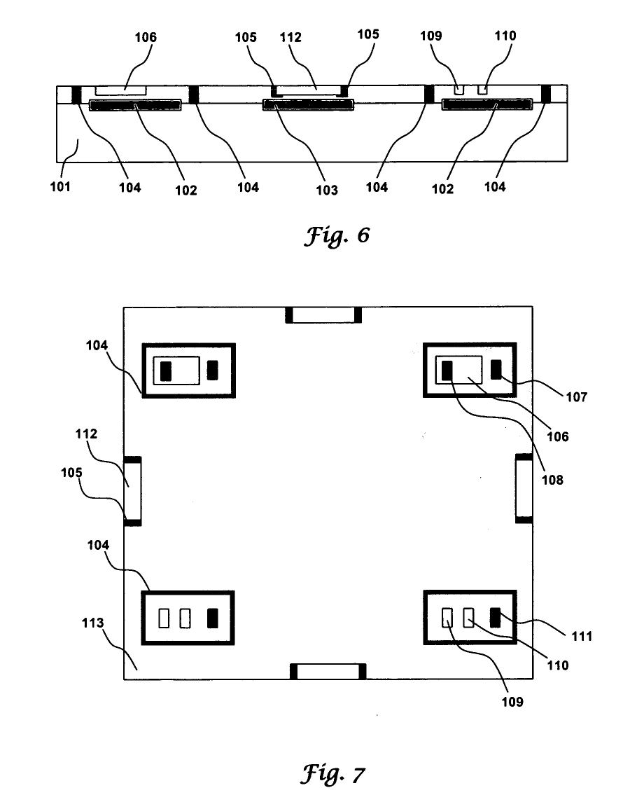

FIG. 6 illustrates a stack with diffusion areas 102, 103, junction isolations 104, readouts 105, piezoresistors 112, transistor elements, and an epitaxial layer 113 in accordance with aspects of the embodiments. The FIG. 6 stack illustrates the formation of transistor elements and piezoresistors 112 into the stack of FIG. 6. P type diffusions in an n type epitaxial layer 113 can be used to create piezoresistors 112, a pnp transistor emitter 109, a pnp transistor collector 110, and an npn transistor base 106.

FIG. 7 illustrates a plan view of junction isolations 104, readouts 105, piezoresistors 112, transistors, and an epitaxial layer 113 in accordance with aspects of the embodiments. FIG. 7 is a plan view of the elements illustrated in FIG. 1. The FIG. 1 stack illustrates the FIG. 6 stack after n type diffusions are used to form the emitter 108 and collector 107 of an npn transistor and the base 111 of a pnp transistor.

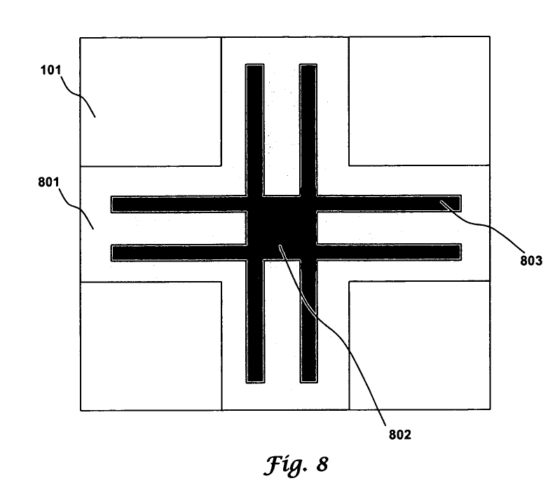

FIG. 8 illustrates a composite diaphragm as seen from the bottom of a substrate 101 in accordance with aspects of the embodiments. The composite diaphragm has a boss 802 and battens 803 that selectively reinforce a thinned area 801. A patterned etch of the substrate 101 bottom etches only the p type material. The thinned area 801, boss 802, and battens 803 are n type and therefore are not etched. The included references, U.S. Pat. No. 6,528,340 and U.S. Pat. No. 6,796,193, also detail the formation of composite diaphragms.

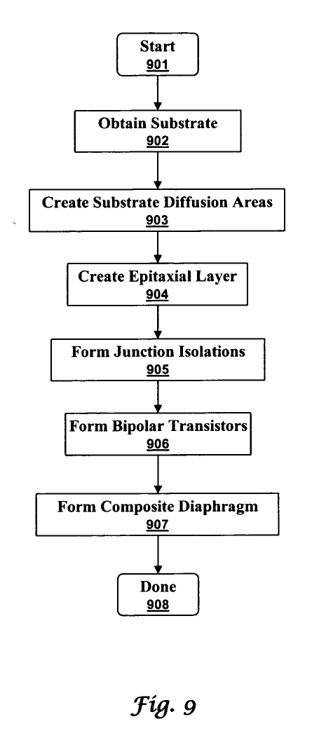

FIG. 9 illustrates a high level flow diagram for simultaneously producing composite diaphragms and transistors in accordance with aspects of the embodiments. After the start 901 a substrate is obtained 902. Diffusion areas are created 903 followed by an epitaxial layer 904. Junction isolations are formed 905 after which transistors are created 906. Finally, the bottom is etch to form the composite diaphragm 907 before the process is done 908.

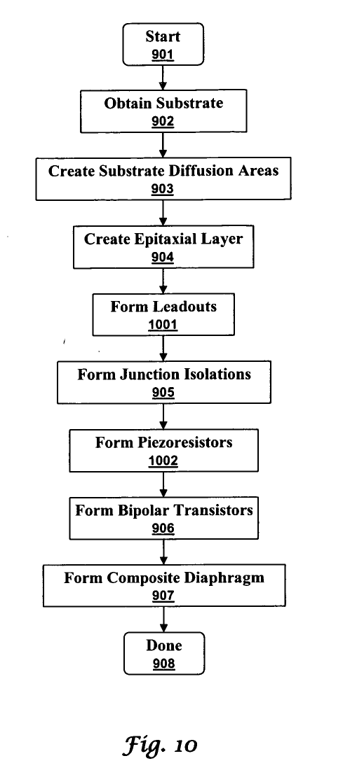

FIG. 10 illustrates a high level flow diagram for simultaneously producing composite diaphragms, piezoresistors, and transistors in accordance with aspects of the embodiments. The FIG. 10 flow diagram is similar to the FIG. 9 flow diagram except for the addition of two steps. Leadouts are formed 1001 and piezoresistors are formed 1002. As illustrated, the readouts are formed 1001 before the junction isolations 905 while in practice readouts can be formed 1001 before or after the junction isolations are formed 905. Similarly, FIG. 10 illustrates piezoresistors formed 1002 before the transistors 906 while in practice piezoresistors can be formed 1002 before or after the transistors are formed 906.

It will be appreciated that variations of the above-disclosed and other features and functions, or alternatives thereof, may be desirably combined into many other different systems or applications. Also that various presently unforeseen or unanticipated alternatives, modifications, variations or improvements therein may be subsequently made by those skilled in the art which are also intended to be encompassed by the following claims.

The embodiments of the invention in which an exclusive property or right is claimed are defined as follows. Having thus described the invention what is claimed is:

1. A method comprising:
obtaining a substrate comprising a top and a bottom;
creating diffusion areas in the top;
creating an epitaxial layer on the top such that the diffusion areas spread into the epitaxial layer;
forming junction isolations to produce at least one transistor area over at least one of the diffusion areas;
forming at least one bipolar transistor within at least one of the transistor areas wherein every bipolar transistor comprises a base, an emitter and a collector; and
etching the back to form a composite diaphragm, thereby simultaneously producing transistors and a composite diaphragm.

2. The method of claim 1 wherein at least one of the at least one bipolar transistor is an npn bipolar transistor.

3. The method of claim 1 wherein at least one of the at least one bipolar transistor is a pnp bipolar transistor.

4. The method of claim 1 wherein the substrate is a p type substrate, the epitaxial layer is an n type epitaxial layer, and wherein the diffusion areas are n type diffusion areas.

5. The method of claim 4 wherein at least one of the at least one bipolar transistor is an npn bipolar transistor and wherein forming the npn bipolar transistor comprises:
forming a base of p type material; and
forming a collector and emitter wherein the collector and the emitter comprise n type material and wherein the emitter comprises a volume of n type material inside the base.

6. The method of claim 4 wherein at least one of the at least one bipolar transistor is a pnp bipolar transistor wherein forming the pnp bipolar transistor comprises:
forming a collector and emitter of p type material; and
forming a base of n type material.

7. A method comprising:
obtaining a substrate comprising a top and a bottom;
creating diffusion areas in the top;
creating an epitaxial layer on the top such that the diffusion areas spread into the epitaxial layer;
forming at least two readouts;
forming junction isolations to produce at least one transistor area over at least one of the diffusion areas;
forming at least one piezoresistor comprising a body, a first end and a second end wherein the first end is electrically connected to a first readout and the second end is electrically connected to a second readout;
forming at least one bipolar transistor within at least one of the transistor areas wherein every bipolar transistor comprises a base, an emitter and a collector; and
etching the back to form a composite diaphragm, thereby simultaneously producing transistors, piezoresistors and a composite diaphragm.

8. The method of claim 7 wherein at least one of the at least one bipolar transistor is an npn bipolar transistor.

9. The method of claim 7 wherein at least one of the at least one bipolar transistor is a pnp bipolar transistor.

10. The method of claim 7 wherein the substrate is a p type substrate, the epitaxial layer is an n type epitaxial layer, and wherein the diffusion areas are n type diffusion areas.

11. The method of claim 10 wherein at least one of the at least one bipolar transistor is an npn bipolar transistor and wherein forming the npn bipolar transistor comprises:
forming a base of p type material; and
forming a collector and emitter wherein the collector and the emitter comprise n type material and wherein the emitter comprises a volume of n type material inside the base.

12. The method of claim 10 wherein at least one of the at least one bipolar transistor is a pnp bipolar transistor wherein forming the pnp bipolar transistor comprises:
forming a collector and emitter of p type material; and
forming a base of n type material.

13. The method of claim 7 wherein forming at least one piezoresistor comprises forming p type diffusions in the epitaxial layer.

14. A system comprising:
a substrate comprising a top and a bottom;
an epitaxial layer on the top and diffusion areas in the top where the diffusion areas extend into the epitaxial layer;
junction isolations enclosing at least one of the diffusion areas to produce transistor areas;
at least one piezoresistor comprising a body, a first end and a second end wherein the first end is electrically connected to a first readout and the second end is electrically connected to a second readout;
at least one bipolar transistor within at least one of the transistor areas wherein every bipolar transistor comprises a base, an emitter and a collector; and
a channel etched into the back to form a composite diaphragm.

15. The system of claim 14 wherein at least one of the at least one bipolar transistor is an npn bipolar transistor.

16. The system of claim 14 wherein at least one of the at least one bipolar transistor is a pnp bipolar transistor.

17. The system of claim 14 wherein the substrate is a p type substrate, the epitaxial layer is an n type epitaxial layer, and wherein the diffusion areas are n type diffusion areas.

18. The system of claim 17 wherein at least one of the at least one bipolar transistor is an npn bipolar transistor wherein the collector comprises a volume of n type material, the base comprises a volume of p type material, and the emitter comprises a volume of n type material inside the base.

19. The system of claim 17 wherein at least one of the at least one bipolar transistor is a pnp bipolar transistor wherein the collector comprises a volume of p type material, the base comprises a volume of n type material, and the emitter comprises a volume of p type material.

20. The system of claim 14 wherein the body of at least one of the at least one piezoresistor comprises a p type area in the epitaxial layer.
